(19) United States
(12) Patent Application Publication
(10) Pub. No.: US 2015/0043145 A1
(43) Pub. Date: Feb. 12, 2015

(54) DISPLAY ASSEMBLY

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventors: Wei-Kuang LIANG, New Taipei (TW); Quan-Guang DU, Shenzhen (CN); Chun TANG, Shenzhen (CN)

(21) Appl. No.: 14/452,165

(22) Filed: Aug. 5, 2014

(30) Foreign Application Priority Data
Aug. 8, 2013 (CN) 2013103432784

(51) Int. Cl. H05K 5/02; G06F 1/16; H05K 5/00

(52) U.S. Cl. CPC H05K 5/0226; H05K 5/0017; H05K 5/0008; G06F 1/1637
USPC 361/679.27

(57) ABSTRACT

A display assembly includes a display, an enclosure, and a first mounting hinge for securing the display to the enclosure. The enclosure defines a receiving opening for receiving the display. The enclosure includes a bottom plate, a securing member, and an inserting member protruding from the bottom plate. The first mounting hinge includes a first head portion, a first axial portion connected to the first head portion, and a first securing portion connected to the first axial portion. The first axial portion is mounted to the display. The first head portion inserts the inserting member to prevent the first mounting hinge from moving along a direction substantially perpendicular to the bottom plate. The first securing portion is mounted to the securing member after the first head portion receives in the inserting member, thereby enabling the display to be mounted to the enclosure.

### FIELD

The subject matter herein generally relates to a display assembly in a notebook.

### BACKGROUND

A notebook, generally, comprises a display, an enclosure, and a hinge for securing the display to the enclosure. The hinge is generally mounted on the enclosure by a plurality of screws. In the process of securing the display, the display need be assembled and disassembled by other tools, such as a screwdriver.

### BRIEF DESCRIPTION OF THE DRAWINGS

Implementations of the present technology will now be described, by way of example only, with reference to the attached figures, wherein:

FIG. 1 is an exploded, isometric view of a display assembly in accordance with an embodiment.

FIG. 2 is an enlarged, isometric view of a circled portion II of the display assembly of FIG. 1.

FIG. 3 is an enlarged, isometric view of a circled portion III of the display assembly of FIG. 1.

FIG. 4 is an exploded, isometric view of a mounting hinge of FIG. 1.

FIG. 5 is an assembled, isometric view of the display assembly of FIG. 1.

FIG. 6 is an enlarged, isometric view of a circled portion VI of FIG. 5.

FIG. 7 is an enlarged, isometric view of a circled portion VII of FIG. 5.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to a display assembly in a notebook.

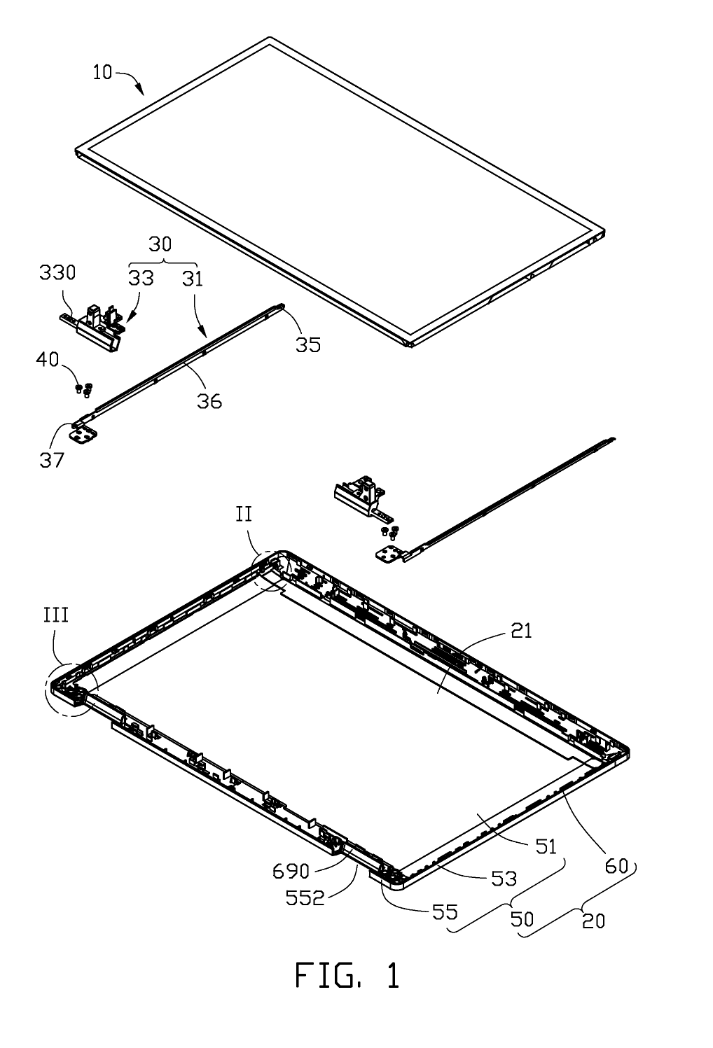

FIG. 1 illustrates a display assembly in accordance with an embodiment comprises a display 10, an enclosure 20, and two mounting members 30 for securing the display 10 to the enclosure 20.

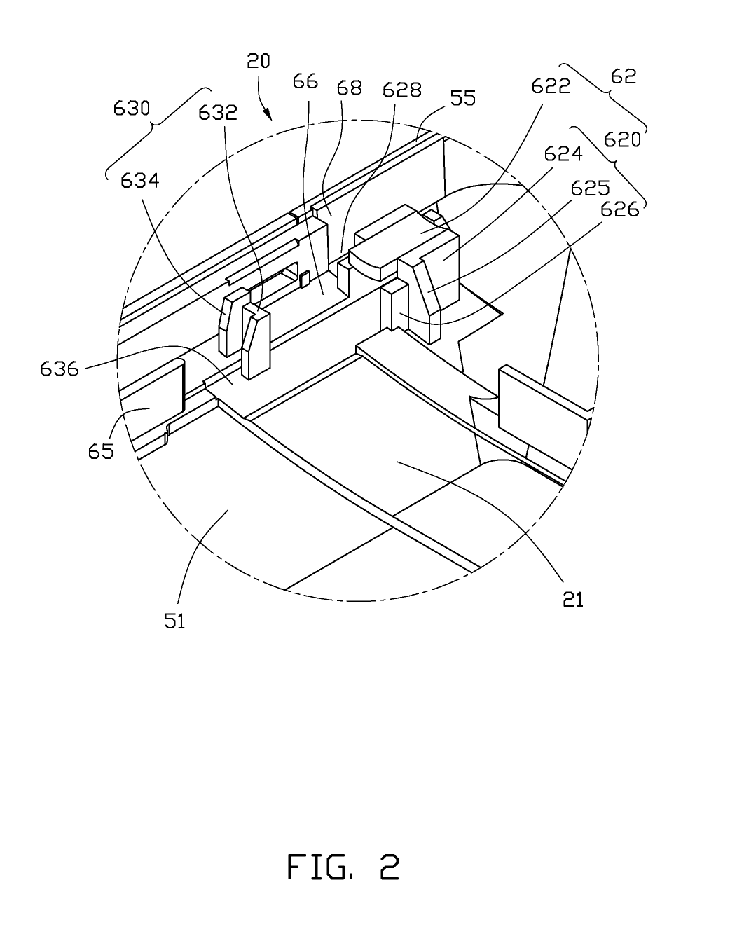

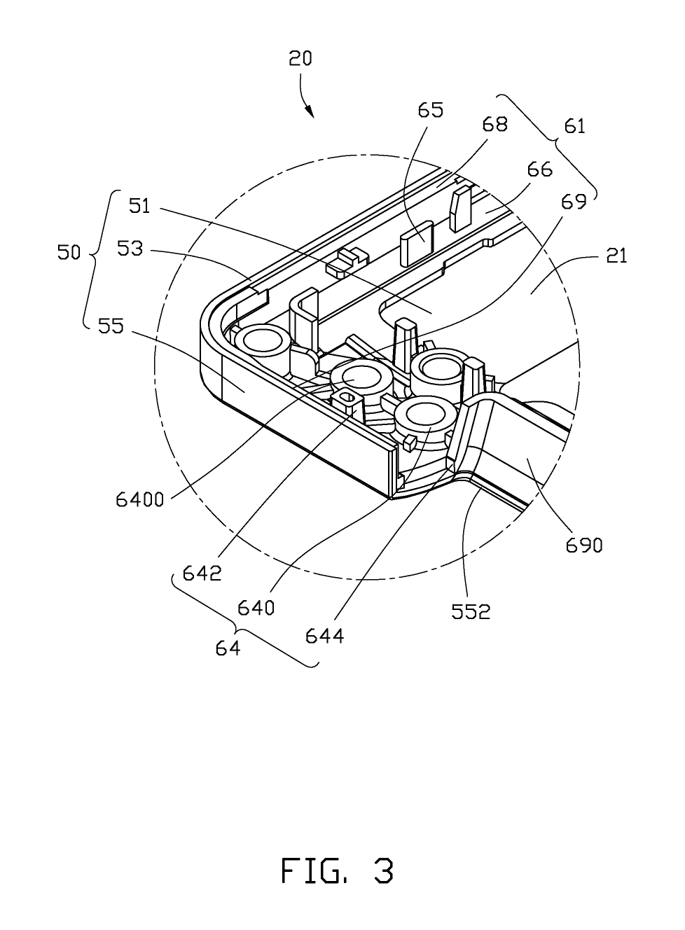

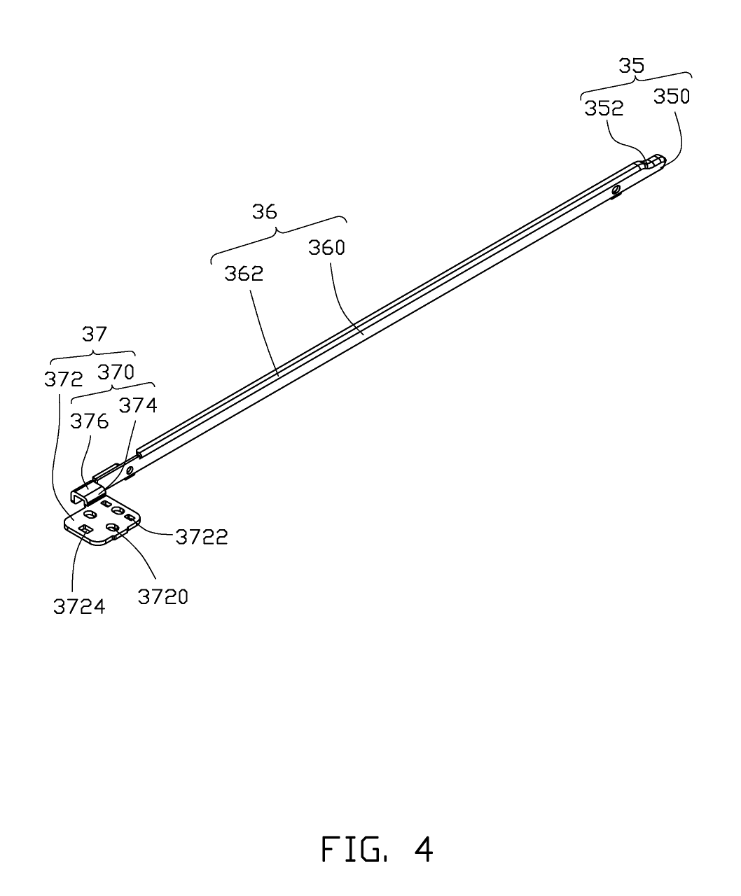

FIGS. 2-4 illustrate, the enclosure 20 comprises a bottom chassis 50 and a bracket 60 mounted on the bottom chassis 50. The enclosure 20 defines a receiving opening 21 for receiving the display 10. The bottom chassis 50 comprises a bottom cover 51, two of first bent walls 53 parallel to each other, and a second bent wall 55 perpendicularly connected to the couple of first bent walls 53. The two first bent walls 53 and the second bent wall 55 extend from three edges of the bottom cover 51. A slot 552 is defined in the second bent wall 55.

The bracket 60 comprises a bracket body 61, two inserting members 62, two protrusions 63, a securing element 64, and a plurality of blocks 65. The bracket body 61 comprises a bottom plate 66, two first side plates 68 substantially perpendicularly extending from the bottom plate 66, and a second side plate 69 substantially perpendicularly extending from the bottom plate 66. The two first side plates 68 are parallel to each other. The second side plate 69 corresponds to the second bent wall 55. The second side plate 69 defines two openings 690. Each opening 690 corresponds to each slot 552. A receiving opening 21 is defined in the bracket body 61. Each inserting member 62 comprises two sidewalls 620 and a top wall 622. Each sidewall 620 comprises a positioning portion 624 connected to the top wall 622, a connection portion 625 perpendicularly connected to the positioning portion 624, and an extending portion 626 connected to the connecting portion 625. The positioning portion 624, the connecting portion 625, and the extending portion 626 perpendicularly extend from the bottom plate 66. A receiving hole 628 is surrounded by the top wall 622, the side portions 624, the connecting portion 625, and the connecting portion 626. Each protrusion 63 comprises a support portion 632 and a resisting portion 634 connected to the support portion 632. The support portion 632 and the resisting portion 634 perpendicularly extend from the bottom plate 66. A channel 636 is formed between the protrusions 63 and the blocks 65. The securing element 64 comprises three first securing posts 640 protruding from the bottom plate 66, a second securing post 642 protruding from the bottom plate 66, and two third securing posts 644 protruding from the bottom plate 66. A locking hole 6400 is defined in each first securing post 640. Each protrusion 65 extends perpendicularly from the bottom plate 66.

Each mounting member 30 comprises a mounting hinge 31 and a securing member 33. The mounting hinge 31 comprises a head portion 35, an axial portion 36 connected to the head portion 35, and a securing portion 37 connected to the axial portion 36. The head portion 35 comprises a first side portion 350 and a first top portion 352 extending from the first side portion 350. The axial portion 36 comprises a second side portion 360 connected to the first side portion 350 and a second top portion 362 extending from the second side portion 360. The second side portion 360 and the first side portion 350 are located in the same plane. The second top portion 362 is connected to the first top portion 352. The securing portion 37 comprises a bent portion 370 and a securing piece 372 connected to the bent portion 370. The bent portion 370 is substantially C-shaped. The bent portion 370 comprises two first side portions 374 and a connecting portion 376 connected to the two first side portions 374. One of the two first side portions 374 is connected to the second side portion 360 and is located in a same plane with the second side portion 360. The securing piece 372 defines three first securing holes 3720, a second securing hole 3722, and two third securing holes 3724. Each first securing hole 3720 corresponds to each first securing post 640. The second securing hole 3722 corresponds to the second securing post 642. Each third securing hole 3724 corresponds to each third securing post 644. Each securing member 33 corresponds to each slot 552 and each opening 690. The securing member 33 defines a mounting hole 330 corresponding to the second mounting post 642.

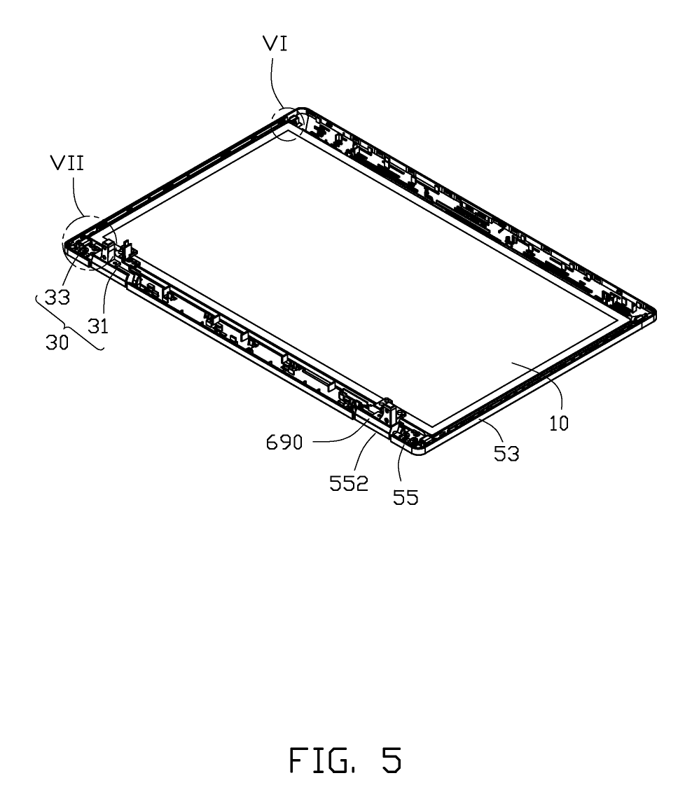

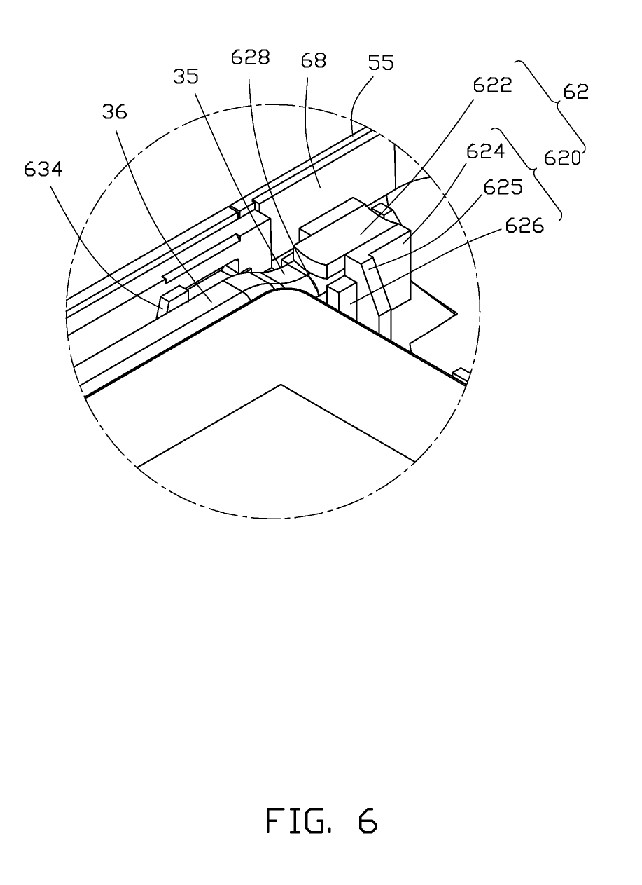

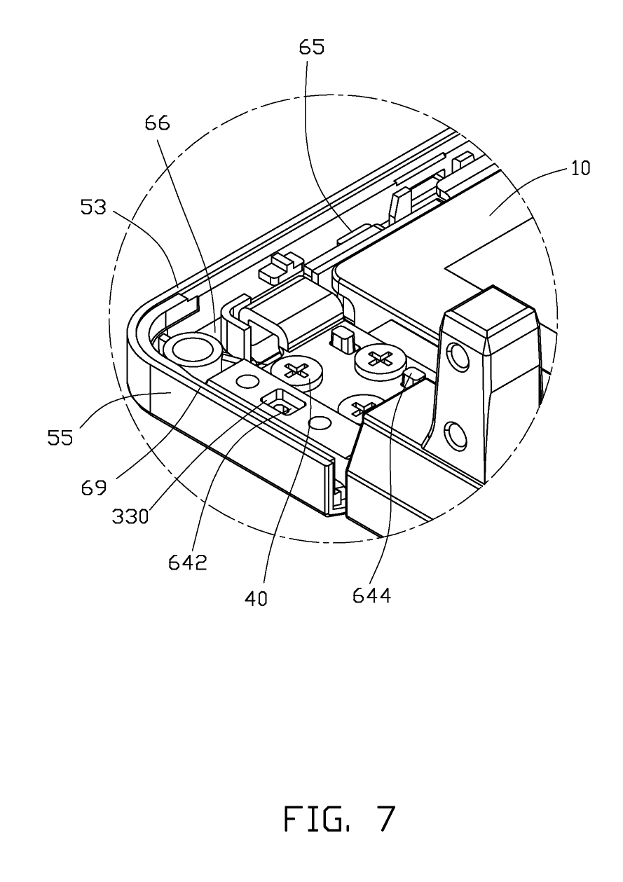

FIGS. 5-7 illustrate that in assembly, the display 10 is secured to the mounting hinge 31 (for example, by way of screws) to enable each mounting hinge 31 to be secured to two sides of the display 10. Then, the display 10 and the mounting hinge 31 are moved to enable the head portion 35 to be inserted into the receiving hole 20 of the channel 628, thereby the first side portion 350 and the second side portion 360 enter the channel 636. The display 10 and the mounting hinge 31 are sequentially moved to enable the display 10 to be received in the receiving opening 21. The securing piece 372 is pressed along a first direction perpendicular to the bottom plate 66 to enable each first mounting post 640 to be located in each first securing hole 3720, the second mounting post 642 to be located in the second securing hole 3722, and each third mounting post 644 to be located in each third securing hole 3724. Thus, the second support portion 632 supports the second top portion 362. The second top portion 362 is located between the second side portion 360 and the resisting portion 634. Each protrusion 65 resists the second side portion 360. The first top portion 352 resists the top wall 622. Each locking hole 6400 is locked by a corresponding locking latch 40. Thus, the display 10 and the mounting hinge 31 are mounted on the enclosure 20. Then, mounting hole 330 of the securing member 33 is aligned with the second securing post 642. The securing member 33 is secured to the mounting hinge 31.

In disassembly, the securing member 33 is dissembled. Then, each locking latch 40 is released. The securing piece 372 is operated along a second direction opposite to the first direction to enable each first securing post 640 to disengage from each first securing hole 3720, the second securing post 642 to disengage from the second securing hole 3722, and each third securing post 644 to disengage from the each third securing hole 3724. The head portion 35 is configured to disengage from the receiving hole 628 along a third direction parallel to the first bent wall 53.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A display assembly comprising:
a display;
an enclosure defining a receiving opening for receiving the display and comprising a bottom plate, a first securing member protruding from the bottom plate, and an first inserting member protruding from the bottom plate; and
a first mounting hinge for securing the display to the enclosure comprising a first head portion, a first axial portion connected to the first head portion, and a first securing portion connected to the first axial portion,
wherein the first axial portion is mounted to the display; the first head portion is configured to be inserted in the first inserting member to prevent the first mounting hinge from moving along a direction; the first securing portion is mounted to the first securing member after the first head portion is configured to be received by the first inserting member, thereby enabling the display to be mounted to the enclosure.

2. The display assembly of claim 1, further comprises a second mounting hinge for securing the display to the enclosure; wherein the second mounting hinge further comprises a second head portion, a second axial portion connected to the second head portion, and a second securing portion connected to the second axial portion; the first mounting hinge and the second hinge are secured to two sides of the display; the enclosure further comprises a second securing member protruding from the bottom plate and a second inserting member protruding from the bottom plate; the second head portion is configured to be inserted in the second inserting member to prevent the second mounting hinge from moving along the direction substantially perpendicular to the bottom plate; the second securing portion is mounted to the second securing member after the second head portion is configured to be received by the second inserting member, thereby enabling the display to be mounted to the enclosure.

3. The display assembly of claim 1, wherein the inserting member comprises a first side wall extending from the bottom plate and a first top wall connected to the first side wall; the first head portion configured to be inserted between the first top wall and the bottom plate to prevent the mounting hinge from moving along the direction.

4. The display assembly of claim 3, wherein a receiving hole is defined in the inserting member; the inserting member further comprises a second side wall extending from the bottom plate; the top wall is connected between the first side wall and the second side wall; the receiving hole is surrounded by the first side wall, the second side wall, and the top wall.

5. The display assembly of claim 4, wherein the side wall comprises a positioning portion connected to the top side wall, a connecting portion connected to the positioning portion, and an extending portion connected to the connecting portion; the positioning portion, the connecting portion, and the extending portion extend from the bottom plate; the receiving hole is surrounded by the top wall, the positioning portion, the connecting portion, and the extending portion.

6. The display assembly of claim 5, wherein the two positioning portions of the two side walls are parallel to each other; the top wall is connected between the two positioning portions.

7. The display assembly of claim 5, wherein each positioning portion is perpendicular to the bottom plate.

8. The display assembly of claim 3, wherein the head comprises a first side portion and a first top portion extending from the first side portion; the first side portion contacts the bottom plate; the first top portion resists the top wall to prevent the mounting hinge from moving along the direction.

9. The display assembly of claim 8, wherein the axial portion comprises a second side portion connected to the first side portion and a second top portion extending from the second side portion; the protrusion comprises a support portion extending from the bottom plate and a resisting portion extending from the bottom plate; the support portion supports the second top portion; the second top portion is located between the resisting portion and the second side portion.

10. The display assembly of claim 1, wherein the support portion is substantially perpendicularly to the bottom plate.

11. A display assembly comprising:
an enclosure comprising a bottom plate, a first securing member protruding from the bottom plate, and a first inserting member protruding from the bottom plate; and
a first mounting hinge for securing a display to the enclosure comprising a first head portion, an first axial portion connected to the first head portion, and a first securing portion connected to the first axial portion,
wherein the first axial portion is secured to the display; the first head portion is configured to be inserted in the first inserting member to prevent the first mounting hinge from moving along a direction substantially perpendicular to the bottom plate; the first securing portion is mounted to the first securing member after the first head portion is configured to be received by the first inserting member, thereby enabling the display to be mounted to the enclosure.

12. The display assembly of claim 11, further comprises a second mounting hinge for securing the display to the enclosure; the second mounting hinge further comprises a second head portion, a second axial portion connected to the second head portion, and a second securing portion connected to the second axial portion; the first mounting hinge and the second hinge are secured to two sides of the display; the enclosure further comprises a second securing member protruding from the bottom plate and a second inserting member protruding from the bottom plate; the second head portion is configured to be inserted in the second inserting member to prevent the second mounting hinge from moving along a direction substantially perpendicular to the bottom plate; the second securing portion is mounted to the second securing member after the second head portion is configured to be receives in the second inserting member, thereby enabling the display to be mounted to the enclosure.

13. The display assembly of claim 11, wherein the inserting member comprises a first side wall extending from the bottom plate and a first top wall connected to the first side wall; the first head portion inserts between the first top wall and the bottom plate to prevent the first mounting hinge from moving along the direction.

14. The display assembly of claim 13, wherein a receiving hole is defined in the inserting member; the inserting member further comprises a second side wall extending from the bottom plate; the top wall is connected between the first side wall and the second side wall; the receiving hole is surrounded by the first side wall, the second side wall, and the top wall.

15. The display assembly of claim 14, wherein the side wall comprises a positioning portion connected to the top side wall, a connecting portion connected to the positioning portion, and an extending portion connected to the connecting portion; the positioning portion, the connecting portion, and the extending portion extend from the bottom plate;
the receiving hole is surrounded by the top wall, the positioning portion, the connecting portion, and the extending portion.

16. The display assembly of claim 15, wherein the two positioning portions of the two side walls are parallel to each other.

17. The display assembly of claim 15, wherein each positioning portion is perpendicular to the bottom plate.

18. The display assembly of claim 13, wherein the head comprises a first side portion and a first top portion extending from the first side portion; the first side portion contacts the bottom plate; the first top portion resists the top wall to prevent the first mounting hinge from moving along the direction.

19. The display assembly of claim 18, wherein the axial portion comprises a second side portion connected to the first side portion and a second top portion extending from the second side portion; the protrusion comprises a support portion extending from the bottom plate and a resisting portion extending from the bottom plate; the support portion supports the second top portion; the second top portion is located between the resisting portion and the second side portion.

20. The display assembly of claim 14, wherein the first side portion and the second side portion are located in the same plane.
